(19) United States
(12) Patent Application Publication
(10) Pub. No.: US 2006/0043425 A1
(43) Pub. Date: Mar. 2, 2006

(54) Semiconductor integrated circuit device which restricts an increase in the area of a chip, an increase in the number of lead terminals of a package, and can reduce parasitic inductance

(75) Inventor: Shoji Sakurai, Osaka (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/211,584

(22) Filed: Aug. 26, 2005

(30) Foreign Application Priority Data
Sep. 2, 2004 (JP) 2004-255950 (P)

(51) Int. Cl. H01L 27/10; H01L 21/44

(52) U.S. Cl. 257/207; 257/728; 257/786; 438/612; 438/128

(57) ABSTRACT

A semiconductor integrated circuit device according to the present invention has a configuration where a GND line is shared by a first circuit block and a second circuit block from among a number of circuit blocks provided on a semiconductor substrate, where the first circuit block and the second circuit block are in a state where they do not operate parallel to each other. In addition, one bonding pad and the GND line are electrically connected to each other. Accordingly, one GND terminal is provided for two circuit blocks, and therefore, it is possible to reduce the number of lead terminals.

This nonprovisional application is based on Japanese Patent Application No. 2004-255950 filed with the Japan Patent Office on Sep. 2, 2004, the entire contents of which are hereby incorporated by reference.

### BACKGROUND OF THE INVENTION

1. Field of the Invention

The present invention relates to a semiconductor integrated circuit device that includes circuits only one of which operates at a time, such as a transmission system circuit and a receiving system circuit of a high frequency communication device, and in particular, to a semiconductor integrated circuit device where electrical connection between an integrated circuit chip and a semiconductor package is made by means of bonding wires.

2. Description of the Background Art

In general, an integrated circuit chip of a semiconductor circuit integrated device (hereinafter also simply referred to as chip) has a number of bonding pads on the upper surface thereof, and this number of bonding pads are aligned in the peripheral region of a circuit that is formed in a chip. Thus, these bonding pads and lead terminals of a semiconductor package (hereinafter also simply referred to as package) that contains the integrated circuit chip are electrically connected by means of bonding wires, so that signal transmission to/reception from the outside and the application of a voltage that is required for the circuit operation are carried out.

Meanwhile, it is known that bonding wires for making electrical connection between bonding pads and lead terminals of a semiconductor package have a parasitic inductance which greatly affects the circuit properties of the integrated circuit chip. This has become a critical problem.

A problem arises in a grounded emitter amplifier circuit, which is cited as an example, where a bonding wire that is connected to a bonding pad to which a ground voltage GND is supplied has a parasitic inductance which occurs significantly degradation of the circuit properties, due to so-called emitter degeneration. Here, emitter degeneration is a phenomenon where the existence of an impedance component between the emitter of a transistor and a grounded point causes degradation in the transconductance of the grounded emitter amplifier circuit due to negative feedback caused by the impedance, and thus, degradation in the power occurs.

In relation to this, Japanese Patent Laying-Open No. 2002-43869 discloses a configuration for avoiding a problem of degradation in the power of an amplifier circuit which accompanies an increase in the ground impedance caused by the inductance or the like. Specifically, a configuration is disclosed, where a second grounding terminal which is connected to a ground voltage GND is provided via a capacity coupling circuit, in addition to a first grounding terminal for supplying a ground voltage GND to a signal amplifier circuit, where the capacitance value of the capacity coupling circuit is set so that the relationship of the impedance between a bonding wire and the capacity coupling circuit leads to a series resonance in the utilized frequency, and thereby, the ground impedance is set at the minimum value, making the occurrence of degradation in the power difficult.

In the configuration disclosed in the above described gazette, however, it is very difficult to determine the optimal capacitance value for reducing the impedance, and also, a problem arises, where the configuration becomes complex.

In particular, in a high frequency circuit, a bonding wire has a parasitic inductance, which greatly affects the circuit properties, and in the case where the range of utilized frequencies of an input signal, that is, the frequency band, is broad, a problem arises, where it is difficult to gain a sufficient effect in the above described configuration.

In accordance with another system, a number of bonding wires are connected in parallel, and thereby, reduction in the parasitic inductance that accompanies the connection of bonding wires becomes possible.

However, reduction in the area of a chip and reduction in the number of lead terminals of the package is generally desired in a semiconductor integrated circuit device, from the point of view of miniaturization and cost reduction, and the above described system has a problem where an increase in the area of a chip, together with an increase in the number of bonding pads and an increase in the number of lead terminals of the package, is possible.

### SUMMARY OF THE INVENTION

The present invention is provided in order to solve the above described problems, and an object of the invention is to provide a semiconductor integrated circuit device which restricts an increase in the area of a chip and an increase in the number of lead terminals of the package, and in addition, can reduce the parasitic inductance in a simple configuration.

A semiconductor integrated circuit device according to the present invention is provided with a number of circuits on a semiconductor substrate. The number of circuits include a first circuit and a second circuit which do not operate parallel to each other. A first power supply line for commonly supplying either the power supply voltage or the ground voltage to the first circuit and the second circuit, which are provided on the semiconductor substrate, is further provided.

Preferably, at least one bonding pad that is electrically connected to the first power supply line is further provided.

In particular, a lead which is provided in a package that contains the semiconductor substrate and receives a voltage supply from the outside, as well as a number of bonding wires for electrically connecting the lead to each of the at least one bonding pad, are additionally provided.

Preferably, at least one of the first and second circuits includes a grounded emitter amplifier circuit.

Preferably, the first circuit corresponds to a receiving system circuit of a high frequency communication circuit, and the second circuit corresponds to a transmission system circuit that does not operate parallel to the receiving system circuit of the high frequency communication circuit.

In particular, a lead which is provided in a package that contains a semiconductor substrate and receives a voltage supply from the outside, and a bonding wire for electrically coupling the lead to at least one bonding pad are further provided. The semiconductor substrate is provided with a number of bonding pads that include the at least one bonding pad. The lead is electrically connected to the at least one bonding pad that can make the length of the bonding wire shorter than that of the other bonding pads, from among the number of bonding pads.

In particular, the first circuit and the second circuit are placed in proximity to the at least one bonding pad, so that the length of the first power supply line becomes short.

Preferably, a second power supply line for commonly supplying the other of the power supply voltage and the ground voltage to the first circuit and the second circuit is further provided.

A semiconductor integrated circuit device of the present invention is provided with a first power supply line for commonly supplying one of a power supply voltage and a ground voltage to a first circuit and a second circuit which do not operate parallel to each other. Accordingly, the number of power supply lines can be reduced, and in addition, the number of terminals which are connected to the power supply lines can be reduced, so as to reduce the area of a chip.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing an integrated circuit chip according to a first embodiment of the present invention;

FIG. 2 is a schematic block diagram showing an integrated circuit chip according to a second embodiment of the present invention;

FIG. 3 is a diagram illustrating the relationship between an integrated circuit chip and lead terminals according to a third embodiment of the present invention;

FIG. 4 is a diagram showing the circuit configuration of a grounded emitter amplifier circuit according to a fourth embodiment of the present invention;

FIG. 5 is a schematic block diagram showing a high frequency communication circuit according to a fifth embodiment of the present invention;

FIG. 6 is a diagram illustrating the relationships of the connection between an integrated circuit chip and lead terminals according to a sixth embodiment of the present invention; and

FIG. 7 is schematic block diagram showing an integrated circuit chip according to a seventh embodiment of the present invention.

### DESCRIPTION OF THE PREFERRED EMBODIMENTS

### First Embodiment

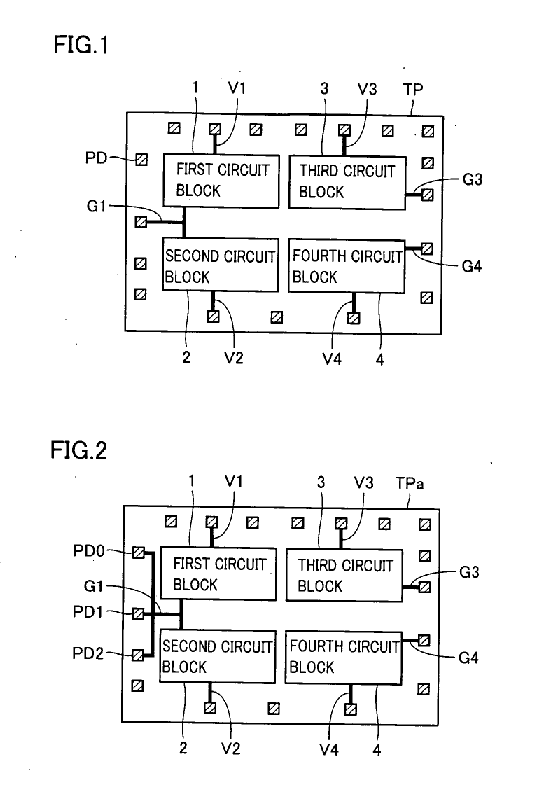

In reference to FIG. 1, an integrated circuit chip TP according to a first embodiment of the present invention includes first to fourth circuit blocks 1 to 4, a number of bonding pads PD which are placed in the peripheral region of the circuit blocks, VDD lines V1 to V4, and GND lines G1, G3 and G4. First to fourth circuit blocks 1 to 4 are connected to respective corresponding VDD lines V1 to V4, so as to receive a supply of a power supply voltage VDD. In addition, first and second circuit blocks 1 and 2 are commonly connected to GND line G1, so as to receive a supply of a ground voltage GND from GND line G1. In addition, third and fourth circuit blocks 3 and 4 receive a supply of ground voltage GND from GND lines G3 and G4, respectively. In the present embodiment, the input/output lines to/from respective circuit blocks 1 to 4 are omitted. Here, the VDD lines and the GND lines are power supply lines for supplying power supply voltage VDD and ground voltage GND, respectively.

Here, the first circuit block and the second circuit block are in a state where they do not operate parallel to each other. The third circuit block and the fourth circuit block are in an arbitrary state of operation.

Lead terminals of a semiconductor integrated circuit device are, in general, separated into three categories, input/output terminals which are electrically connected to input/output lines, power supply terminals which are electrically connected to VDD lines, and GND terminals which are electrically connected to GND lines. Thus, in general, a VDD line and a GND line are provided independently for each circuit block in the configuration, taking effects of noise and the like into consideration. Accordingly, in the case where the number of circuit blocks on an integrated circuit chip increases, the number of required VDD and GND lines increases accordingly, and therefore, the circuit scale of the semiconductor integrated circuit device becomes great, and the number of bonding pads for the connection to lines increases. Namely, the number of lead terminals of the semiconductor package which are connected to the bonding pads also increases.

In the case of a semiconductor integrated circuit device that includes circuits only one of which operates at a time, such as a transmission system circuit and a receiving system circuit of a high frequency communication device, however, the circuit that is not operating does not generate noise. That is to say, even in the case where a GND line is shared by the two circuits, only one circuit operates at a time, and noise from the other does not become a problem.

Thus, the semiconductor integrated circuit device of the present invention has a configuration where GND line G1 is shared by first circuit block 1 and second circuit block 2, which are in a state where they do not operate parallel to each other, from among the number of circuit blocks provided on the semiconductor substrate.

In the present embodiment, a single bonding pad and a GND line are connected to each other. Accordingly, one GND terminal is used for the two circuit blocks, and therefore, it is possible to reduce the number of lead terminals.

Here, though in the present embodiment, the pair of the first circuit block and the second circuit block, which are in a state where they do not operate parallel to each other is described as an example, in the case where a number of pairs which are similar to this exist in a semiconductor chip, GND lines are shared in accordance with the same system, and thereby, it becomes possible to reduce the number of GND terminals relative to the number of circuit blocks. As a result of this, the scale of the circuit of the semiconductor integrated circuit device can be reduced, and the number of lead terminals of the package can be reduced accordingly.

### Second Embodiment

In reference to FIG. 2, an integrated circuit chip TPa according to a second embodiment of the present invention is different from integrated circuit chip TP according to the first embodiment of the present invention, in that GND line G1 is connected to three bonding pads PD0 to PD2. Other portions are the same as in integrated circuit chip TP of FIG. 1, and therefore, the detailed descriptions thereof are not repeated. Here, parts that are the same in the respective drawings are denoted by the same symbols.

In the chip configuration according to the second embodiment of the present invention, the above described GND line GI is shared by a number of circuit blocks, providing a state of connection to a number of bonding pads PD that are not being utilized, and therefore, it becomes possible to reduce the parasitic inductance, due to the connection of a plurality of bonding wires, while restricting an increase in the number of GND terminals as a whole.

Here, though in the present embodiment, a configuration where GND line GI is connected to three bonding pads PD0 to PD2 is described, the invention is not limited to this, but rather, a GND line may be connected to a greater number of bonding parts, and thereby, further reduction in the parasitic inductance can be achieved.

Third Embodiment

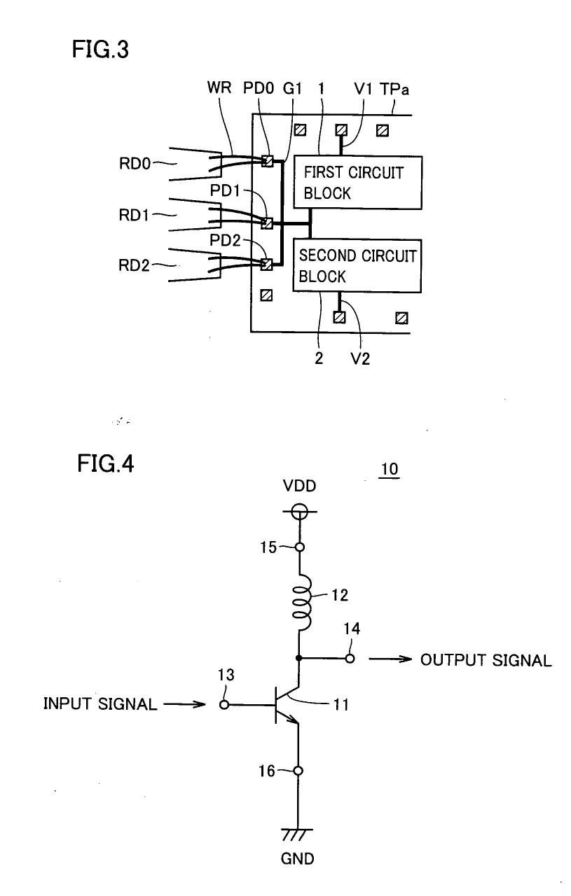

In reference to FIG. 3, the relationship between an integrated circuit chip TPa and lead terminals according to a third embodiment of the present invention is described.

In reference to FIG. 3, lead terminals RD0 to RD2 of a semiconductor package are shown according to the present embodiment. Bonding pads PD0 to PD2 are connected to lead terminals RD0 to RD2 of the semiconductor package, respectively, by means of bonding wires. Thus, according to the present embodiment, there are a number of bonding wires for electrically connecting the lead terminals to the corresponding bonding pads. Though according to the present embodiment, two bonding wires are connected to the respective bonding pads, the number is not limited to two, but rather, it is possible for the number to be greater.

The number of bonding wires which are connected in parallel in the configuration increases according to the present the third embodiment, and thereby, further reduction in the parasitic inductance becomes possible.

### Fourth Embodiment

In reference to FIG. 4, a grounded emitter amplifier circuit 10 according to a fourth embodiment of the present invention includes a bipolar transistor 11, a load inductor 12, an input terminal 13 for grounded emitter amplifier circuit 10, an output terminal 14 for grounded emitter amplifier circuit 10, a power supply terminal 15 that is connected to a VDD line, and a GND terminal 16 that is connected to a GND line.

Grounded emitter amplifier circuit 10 amplifies an input signal from input terminal 13 by a predetermined amplification ratio on the basis of load inductor 12 and bipolar transistor 11, and outputs the resulting signal to output terminal 14.

In the case where such a grounded emitter amplifier circuit 10 is provided as a first circuit block in FIGS. 1 to 3, for example, the impedance between the emitter and the ground of the grounded emitter amplifier circuit is reduced when GND terminal 16 is connected to the GND line, as in FIGS. 1 to 3. Accordingly, degradation in the transconductance caused by emitter degeneration is suppressed, and a signal can be amplified by a desired amplification ratio.

According to the present embodiment, at least one of the first circuit block and the second circuit block, which are in a state where they do not operate parallel to each other, includes a grounded emitter amplifier circuit. As described in the above, a grounded emitter amplifier circuit is very sensitive to parasitic inductance, and therefore, usually requires a number of GND terminals as a preventive measure. According to the present invention, however, it becomes possible to restrict an increase in the number of GND terminals. Furthermore, in the case where a number of bonding wires, as described in the third embodiment, are connected in parallel to a GND terminal of a circuit that requires a reduction in parasitic inductance, such as a grounded emitter amplifier circuit, an increase in the number of GND terminals can further be restricted.

### Fifth Embodiment

According to a fifth embodiment of the present invention, a case of application to a high frequency communication circuit 100 is described as a concrete example of a configuration of the above described semiconductor integrated circuit device.

In reference to FIG. 5, a high frequency communication circuit 100 according to the fifth embodiment of the present invention includes a low noise amplifier (LNA) 20, mixers 21 and 31, band pass filters 22 and 32, a demodulator 23, a power amplifier (PA) 30, a modulator 33, a PLL 40, and local oscillators (VCO) 41 and 42. LNA 20, mixer 21, band pass filter 22 and demodulator 23 form a circuit block 24 in a receiving system (hereinafter also referred to as receiving system circuit block 24). In addition, PA 30, mixer 31, band pass filter 32 and modulator 33 form a circuit block 34 in a transmission system (hereinafter also referred to as transmission system circuit block 34). Receiving system and transmission system circuit blocks 24 and 34 are in a state where they do not operate parallel to each other. Local oscillators 41 and 42, as well as PLL 40, are in a state of operation both in the case where the system is in the state of receiving and in the case where it is in the state of transmission.

In addition, high frequency communication circuit 100 is provided with an input terminal 50 for receiving system circuit block 24, an output terminal 56 for receiving system circuit block 24, an output terminal 52 for transmission system circuit block 34, an input terminal 54 for transmission system circuit block 34, a GND terminal 51 which is shared by LNA and PA, a GND terminal 53 which is shared by two mixers 21 and 31 in receiving system and transmission system circuit blocks 24 and 34, and a GND terminal 55 which is shared by demodulator 23 and modulator 33.

Next, the operation of high frequency communication circuit 100 is described.

When high frequency communication circuit 100 is in a state of receiving, transmission system circuit block 34 is in a state of non-operation, and receiving system circuit block 24 and other circuits are in a state of operation. A received signal that is inputted into input terminal 50 in the receiving system is amplified in LNA 20, and after that, multiplied by an output signal from local oscillator 42 by means of mixer 21 so as to be down converted to a desired frequency. Unnecessary frequency components are removed from the down converted signal by means of band pass filter 22, and after that, the signal is demodulated by demodulator 23 on the basis of an output signal from local oscillator 41 and outputted from output terminal 56 of receiving system circuit block 24.

Meanwhile, when high frequency communication circuit 100 is in the state of transmission, receiving system circuit block 24 is in a state of non-operation, and transmission system circuit block 34 and other circuits are in a state of operation. A transmission signal that is inputted into input terminal 54 of the transmission system circuit block is modulated in modulator 33 on the basis of an output signal from local oscillator 41, and after that, unnecessary frequency components are removed by means of band pass filter 32, and the resulting signal is inputted into mixer 31. This transmission signal is multiplied by an output signal from local oscillator 42 in mixer 31, up converted to a desired frequency, amplified in PA 30, and after that, outputted from output terminal 52 in the transmission system. Here, PLL 40 sets the oscillation frequency of the output signals from local oscillators 41 and 42 to desired frequencies.

According to the present embodiment, a case where GND lines are shared by a pair of LNA 20 and PA 30, a pair of mixer 21 in the receiving system circuit block and mixer 31 in the transmission system circuit block, and a pair of demodulator 23 and modulator 33, is shown as an example. Specifically, ground voltage GND is supplied to LNA 20 and PA 30 via GND terminal 51. Ground voltage GND is supplied to receiving mixer 21 and mixer 31 via GND terminal 53. Ground voltage GND is supplied to modulator 23 and demodulator 33 via GND terminal 55. Here, though a configuration where GND lines are shared by these three pairs is described, the invention is not limited to this, but rather, a GND line may be shared by an arbitrary pair of a circuit that forms receiving system circuit block 24 and a circuit that forms transmission system circuit block 34, which are in a state where they do not operate in parallel in the configuration.

When a high frequency communication circuit is integrated on the same semiconductor substrate, a great number of circuit blocks exist, and therefore, usually, many lead terminals become necessary. However, the state of operation of circuits differs in a high frequency communication circuit, between in the case where the system is in a state of transmission and in the case where it is in a state of receiving, as described above, and the above described pair of a receiving system circuit block and a transmission system circuit block exists where a GND line is shared, and thereby, the number of bonding pads can be reduced, and as a result, it becomes possible to reduce the number of lead terminals.

### Sixth Embodiment

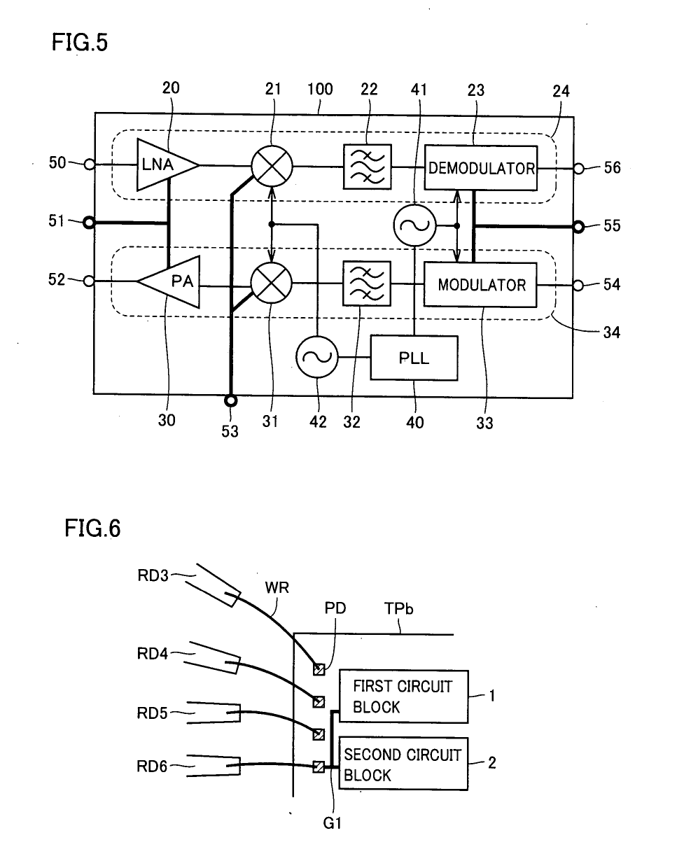

In reference to FIG. 6, the relationships of the connection between an integrated circuit chip TPb and lead terminals according a to sixth embodiment of the present invention is described.

In reference to FIG. 6, lead terminals RD3 to RD6 are provided in the present embodiment. In addition, a GND line G1 shared by a first circuit block 1 and a second circuit block 2 is provided.

As shown in FIG. 6, the length of a bonding wire is determined by the position of a bonding pad and a lead terminal which are connected by the wire, and therefore, the length differs for respective bonding wires. The wires that are connected to pads in the vicinity of four corners of a semiconductor chip, for example, tend to be longer than other wires. It is desirable to make bonding wires as short as possible, in order to reduce parasitic inductance.

The pad that is in a position that makes the length of a bonding wire the shortest is connected to a shared GND line, and thereby, parasitic inductance is reduced. Specifically, the pad that can make the length of the bonding wire the shortest, from among a number of pads that are adjacent to a lead terminal RD, is connected to lead terminal RD with a bonding wire WR.

In addition, as is well known, the longer a GND line is on a semiconductor chip, the greater parasitic capacitance and parasitic inductance increases, and therefore, it is desirable for GND to be as short as possible.

Accordingly, it becomes possible to further reduce parasitic impedance by placing first and second circuit blocks 1 and 2 which are connected to a GND line in proximity to the bonding pad that is connected to lead terminal RD in order to make the GND line short.

### Seventh Embodiment

Though in the above described embodiments, a configuration where an increase in the number of GND terminals is prevented and the parasitic inductance is reduced by sharing GND lines is described, such a configuration is applicable to VDD lines, in addition to GND lines, in exactly the same manner.

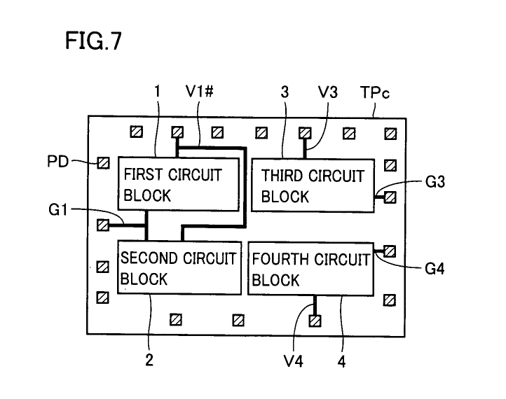

In reference to FIG. 7, a VDD line V1#, in addition to a GND line G1, is shared by a first circuit block and a second circuit block in an integrated circuit chip TPC according to a seventh embodiment of the present invention.

In the semiconductor integrated circuit device of the present invention, a VDD line is shared by a first circuit block and a second circuit block. Accordingly, it becomes possible to reduce the area of a chip and the number of lead terminals of a package, by making a VDD line be shared. Here, this configuration is applicable to the above described embodiments first to sixth, in the same manner.

Although the present invention has been described and illustrated in detail, it is clearly understood that the same is by way of illustration and example only and is not to be taken by way of limitation, the spirit and scope of the present invention being limited only by the terms of the appended claims.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor integrated circuit device, comprising a number of circuits provided on a semiconductor substrate, wherein
said number of circuits include a first circuit and a second circuit which do not operate parallel to each other, and
the semiconductor integrated circuit device further comprises a first power supply line which is shared by and supplies one of a power supply voltage and a ground voltage to said first circuit and said second circuit provided on said semiconductor substrate.

2. The semiconductor integrated circuit device according to claim 1, further comprising at least one bonding pad that is electrically connected to said first power supply line.

3. The semiconductor integrated circuit device according to claim 2, further comprising:
a lead which is provided in a package that contains said semiconductor substrate and which receives a voltage supply from the outside; and
a number of bonding wires for electrically connecting said lead to each of said at least one bonding pad.

4. The semiconductor integrated circuit device according to claim 2, further comprising:
a lead which is provided in a package that contains said semiconductor substrate and which receives a voltage supply from the outside; and
a bonding wire for electrically connecting said lead to each of said at least one bonding pad, wherein
said semiconductor substrate comprises a number of bonding pads that include said at least one bonding pad, and
said lead is electrically connected to said at least one bonding pad that can make the length of said bonding wire shorter than that of the other bonding pads, from among said number of bonding pads.

5. The semiconductor integrated circuit device according to claim 2, wherein said first circuit and said second circuit are placed in proximity to said at least one bonding pad, in a manner where the length of said first power supply line becomes short.

6. The semiconductor integrated circuit device according to claim 1, wherein at least one of said first and second circuits includes a grounded emitter amplifier circuit.

7. The semiconductor integrated circuit device according to claim 1, wherein
said first circuit corresponds to the receiving system circuit of a high frequency communication circuit, and said second circuit corresponds to a transmission system circuit that does not operate parallel to said receiving system circuit of said high frequency communication circuit.

8. The semiconductor integrated circuit device according to claim 1, further comprising
a second power supply line which is shared by and supplies the other of said power supply voltage and said ground voltage to said first circuit and said second circuit.
